(19) United States
(12) Patent Application Publication
(10) Pub. No.: US 2004/0212399 A1
(43) Pub. Date: Oct. 28, 2004

(54) Programmable driver for use in a multiple function handheld device

(76) Inventors: Daniel Mulligan, Austin, TX (US); Matthew Brady Henson, Austin, TX (US); Fujio Takeda, Austin, TX (US)

Correspondence Address: GARLICK HARRISON & MARKISON LLP, P.O. BOX 160727, AUSTIN, TX, 78716-0727, US

(21) Appl. No.: 10/723,169

(22) Filed: Nov. 26, 2003

Related U.S. Application Data
(60) Provisional application No. 60/429,941, filed on Nov. 29, 2002.

(51) Int. Cl. H03K 19/0175

(52) U.S. Cl. 326/90

(57) ABSTRACT

A programmable driver includes a first driver, a second driver, and a controller. The second driver is operably coupled in parallel with the first driver to drive a signal on to a line at a first drive level when a drive control signal is in a first state and wherein, when the drive control signal is in a second state, the second driver is in a high-impedance state such that the first driver drives the signal on to the line at a second drive level, wherein the first drive level is greater than the second drive level. The controller is operably coupled to generate the drive control signal based on load requirements of the line.

### CROSS REFERENCE TO RELATED PATENTS

This patent application is claiming priority under 35 USC §119 to provisionally filed patent application entitled MULTI-FUNCTION HANDHELD DEVICE, having a provisional serial No. of 60/429,941, and a filing date of Nov. 29, 2002.

### BACKGROUND OF THE INVENTION

1. Technical Field of the Invention

This invention relates generally to portable electronic equipment and more particularly to a multi-function handheld device.

2. Description of Related Art

As is known, integrated circuits are used in a wide variety of electronic equipment, including portable, or handheld, devices. Such handheld devices include personal digital assistants (PDA), CD players, MP3 players, DVD players, AM/FM radios, pagers, cellular telephones, computer memory extensions (commonly referred to as thumb drives), etc. Each of these handheld devices includes one or more integrated circuits to provide the functionality of the device. For example, a thumb drive may include an integrated circuit for interfacing with a computer (e.g., personal computer, laptop, server, workstation, etc.) via one of the ports of the computer (e.g., Universal Serial Bus, parallel port, etc.) and at least one other memory integrated circuit (e.g., flash memory). As such, when the thumb drive is coupled to a computer, data can be read from and written to the memory of the thumb drive. Accordingly, a user may store personalized information (e.g., presentations, Internet access account information, etc.) on his/her thumb drive and use any computer to access the information.

As another example, an MP3 player may include multiple integrated circuits to support the storage and playback of digitally formatted audio (i.e., formatted in accordance with the MP3 specification). As is known, one integrated circuit may be used for interfacing with a computer, another integrated circuit for generating a power supply voltage, another for processing the storage and/or playback of the digitally formatted audio data, and still another for rendering the playback of the digitally formatted audio data audible.

A critical issue with handheld devices is balancing performance with power conservation. In particular, when a handheld device is providing an output signal (e.g., an audio output signal), it does so at a maximum power level regardless of the load it is driving. However, for most handheld devices, the load may vary considerably. For example, an MP3 may drive headphones or speakers, where the speakers have significantly lower impedance than the headphones. Thus, driving the headphones with the same power level as speakers consumes unnecessary power, which reduces the battery life of the handheld device.

Therefore, a need exists for a programmable driver for use on an integrated circuit that provides multiple functions for handheld devices.

### BRIEF SUMMARY OF THE INVENTION

The programmable driver for use on an integrated circuit of a multiple function handheld device of the present invention substantially meets these needs and others. In one embodiment, a programmable driver includes a first driver, a second driver, and a controller. The second driver is operably coupled in parallel with the first driver to drive a signal on to a line at a first drive level when a drive control signal is in a first state and wherein, when the drive control signal is in a second state, the second driver is in a high-impedance state such that the first driver drives the signal on to the line at a second drive level, wherein the first drive level is greater than the second drive level. The controller is operably coupled to generate the drive control signal based on load requirements of the line.

In another embodiment, a programmable driver includes a plurality of tri-state drivers and a controller. The controller is operably coupled to the plurality of tri-state drivers, wherein, based on a line drive requirement, the controller generates a drive control signal that activates at least one of the plurality of tri-state drivers to drive a signal on to a line at a drive level corresponding to the line drive requirement.

### BRIEF DESCRIPTION OF THE SEVERAL VIEWS OF THE DRAWINGS

FIG. 1 is a schematic block diagram of a multi-function handheld device in accordance with the present invention;

FIG. 2 is a schematic block diagram of another multi-function handheld device in accordance with the present invention;

FIG. 3 is a schematic block diagram of a programmable driver in accordance with the present invention;

FIG. 4 is a schematic block diagram of another programmable driver in accordance with the present invention; and

FIG. 5 is a table illustrating programming of the programmable driver of FIG. 4.

### DETAILED DESCRIPTION OF THE INVENTION

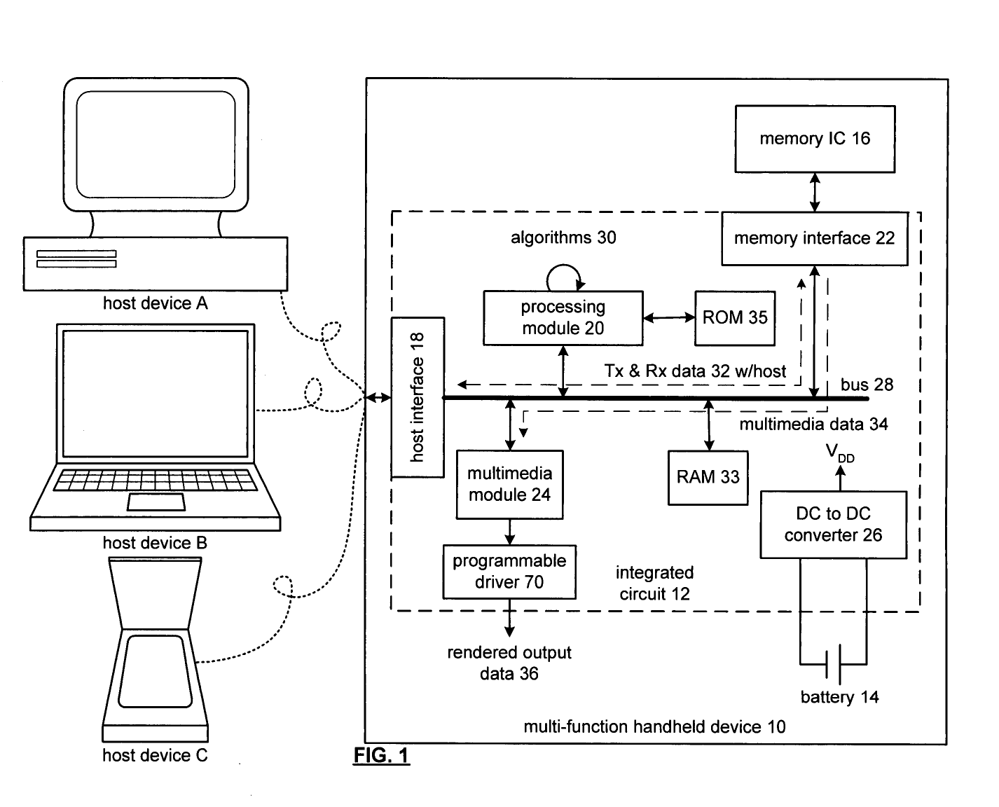

FIG. 1 is a schematic block diagram of a multi-function handheld device 10 that is operably coupled to a host device A, B, or C. The multi-function handheld device 10 includes an integrated circuit 12, memory integrated circuit (IC) 16, and a battery 14. The integrated circuit 12 includes a host interface 18, a processing module 20, a memory interface 22, a multimedia module 24, a DC-to-DC converter 26, read only memory 35, random access memory 33, a programmable driver 70, and a bus 28. The multimedia module 24 alone or in combination with the processing module 20 provides the functional circuitry for the integrated circuit 12. The DC-to-DC converter 26, which may be constructed in accordance with the teaching of U.S. Pat. No. 6,204,651, entitled METHOD AND APPARATUS FOR REGULATING A DC VOLTAGE, provides at least a first supply voltage to one or more of the host interface 18, the processing module 20, the multimedia module 24, and the memory interface 22. The DC-to-DC converter 26 may also provide V_{DD} to one or more of the other components of the handheld device 10.

When the multi-function handheld device 10 is operably coupled to a host device A, B, or C, which may be a personal computer, workstation, server (which are represented by host device A), a laptop computer (host device B), a personal digital assistant (host device C), and/or any other device that may transceive data with the multi-function handheld device, the processing module 20 performs at least one algorithm 30, where the corresponding operational instructions of the algorithm 30 are stored in memory 16 and/or in memory incorporated in the processing module 20. The processing module 20 may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The associated memory may be a single memory device or a plurality of memory devices. Such a memory device may be a read-only memory, random access memory, volatile memory, non-volatile memory, static memory, dynamic memory, flash memory, and/or any device that stores digital information. Note that when the processing module 20 implements one or more of its functions via a state machine, analog circuitry, digital circuitry, and/or logic circuitry, the associated memory storing the corresponding operational instructions is embedded with the circuitry comprising the state machine, analog circuitry, digital circuitry, and/or logic circuitry.

With the multi-function handheld device 10 in the first functional mode, the integrated circuit 12 facilitates the transfer of data between the host device A, B, or C and memory 16, which may be non-volatile memory (e.g., flash memory, disk memory, SDRAM) and/or volatile memory (e.g., DRAM). In one embodiment, the memory IC 16 is a NAND flash memory that stores both data and the operational instructions of at least some of the algorithms 30.

In the first functional mode, the processing module 30 retrieves a first set of operational instructions (e.g., a file system algorithm, which is known in the art) from the memory 16 to coordinate the transfer of data. For example, data received from the host device A, B, or C (e.g., Rx data) is first received via the host interface module 18. Depending on the type of coupling between the host device and the handheld device 10, the received data will be formatted in a particular manner. For example, if the handheld device 10 is coupled to the host device via a USB cable, the received data will be in accordance with the format proscribed by the USB specification. The host interface module 18 converts the format of the received data (e.g., USB format) into a desired format by removing overhead data that corresponds to the format of the received data and storing the remaining data as data words. The size of the data words generally corresponds directly to, or a multiple of, the bus width of bus 28 and the word line size (i.e., the size of data stored in a line of memory) of memory 16. Under the control of the processing module 20, the data words are provided, via the memory interface 22, to memory 16 for storage. In this mode, the handheld device 10 is functioning as extended memory of the host device (e.g., like a thumb drive).

In furtherance of the first functional mode, the host device may retrieve data (e.g., Tx data) from memory 16 as if the memory were part of the computer. Accordingly, the host device provides a read command to the handheld device, which is received via the host interface 18. The host interface 18 converts the read request into a generic format and provides the request to the processing module 20. The processing module 20 interprets the read request and coordinates the retrieval of the requested data from memory 16 via the memory interface 22. The retrieved data (e.g., Tx data) is provided to the host interface 18, which converts the format of the retrieved data from the generic format of the handheld device into the format of the coupling between the handheld device and the host device. The host interface 18 then provides the formatted data to the host device via the coupling.

The coupling between the host device and the handheld device may be a wireless connection or a wired connection. For instance, a wireless connection may be in accordance with Bluetooth, IEEE 802.11(a), (b) or (g), and/or any other wireless LAN (local area network) protocol, IrDA, etc. The wired connection may be in accordance with one or more Ethernet protocols, Firewire, USB, etc. Depending on the particular type of connection, the host interface module 18 includes a corresponding encoder and decoder. For example, when the handheld device 10 is coupled to the host device via a USB cable, the host interface module 18 includes a USB encoder and a USB decoder.

As one of average skill in the art will appreciate, the data stored in memory 16, which may have 64 Mbytes or greater of storage capacity, may be text files, presentation files, user profile information for access to varies computer services (e.g., Internet access, email, etc.), digital audio files (e.g., MP3 files, WMA—Windows Media Architecture-, MP3 PRO, Ogg Vorbis, AAC—Advanced Audio Coding), digital video files [e.g., still images or motion video such as MPEG (motion picture expert group) files, JPEG (joint photographic expert group) files, etc.], address book information, and/or any other type of information that may be stored in a digital format. As one of average skill in the art will further appreciate, when the handheld device 10 is coupled to the host device A, B, or C, the host device may power the handheld device 10 such that the battery is unused.

When the handheld device 10 is not coupled to the host device, the processing module 20 executes an algorithm 30 to detect the disconnection and to place the handheld device in a second operational mode. In the second operational mode, the processing module 20 retrieves, and subsequently executes, a second set of operational instructions from memory 16 to support the second operational mode. For example, the second operational mode may correspond to MP3 file playback, digital dictaphone recording, MPEG file playback, JPEG file playback, text messaging display, cellular telephone functionality, and/or AM/FM radio reception. Each of these functions is known in the art, thus no further discussion of the particular implementation of these functions will be provided except to further illustrate the concepts of the present invention.

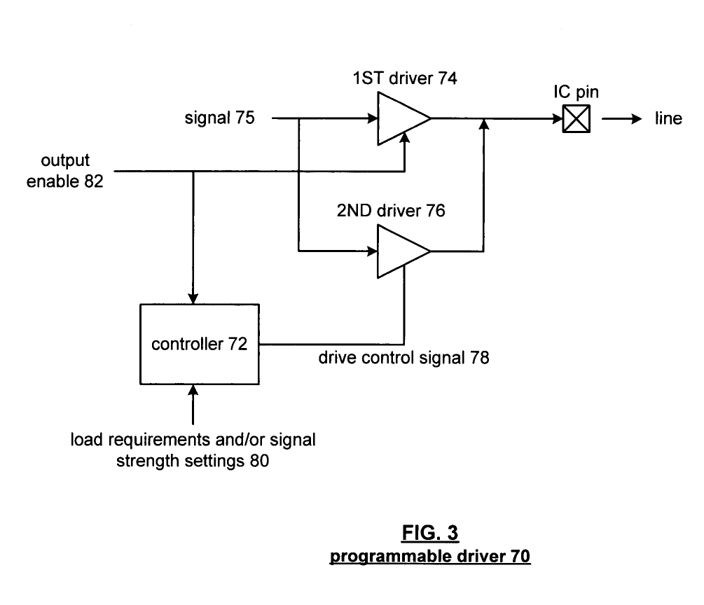

In the second operational mode, under the control of the processing module 20 executing the second set of operational instructions, the multimedia module 24 retrieves multimedia data 34 from memory 16. The multimedia data 34 includes at least one of digitized audio data, digital video data, and text data. Upon retrieval of the multimedia data, the multimedia module 24 converts the data 34 into rendered output data 36 that is outputted via the programmable driver 70, which will be described in greater detail with reference to FIGS. 3-5. For example, the multimedia module 24 may convert digitized data into analog signals that are subsequently rendered audible via a speaker or via a headphone jack. In addition, or in the alternative, the multimedia module 24 may render digital video data and/or digital text data into RGB (red-green-blue), YUV, etc., data for display on an LCD (liquid crystal display) monitor, projection CRT, and/or on a plasma type display.

As one of average skill in the art, the handheld device 10 may be packaged similarly to a thumb drive, a cellular telephone, pager (e.g., text messaging), a PDA, an MP3 player, a radio, and/or a digital dictaphone and offer the corresponding functions of multiple ones of the handheld devices (e.g., provide a combination of a thumb drive and MP3 player/recorder, a combination of a thumb drive, MP3 player/recorder, and a radio, a combination of a thumb drive, MP3 player/recorder, and a digital dictaphone, combination of a thumb drive, MP3 player/recorder, radio, digital dictaphone, and cellular telephone, etc.).

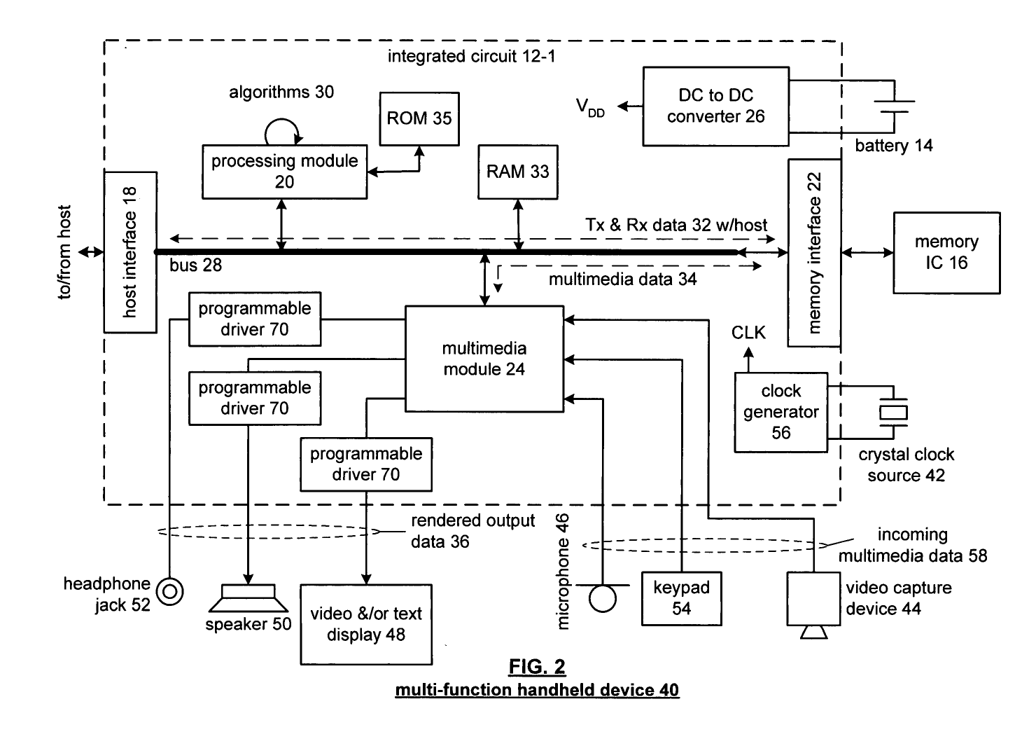

FIG. 2 is a schematic block diagram of another handheld device 40 that includes the integrated circuit 12, the battery 14, the memory 16, a crystal clock source 42, one or more multimedia input devices (e.g., one or more video capture device(s) 44, keypad(s) 54, microphone(s) 46, etc.), and one or more multimedia output devices (e.g., one or more video and/or text display(s) 48, speaker(s) 50, headphone jack(s) 52, etc.). The integrated circuit 12 includes the host interface 18, the processing module 20, the memory interface 22, the multimedia module 24, the DC-to-DC converter 26, a plurality of programmable drivers 70, and a clock generator 56, which produces a clock signal (CLK) for use by the other modules. As one of average skill in the art will appreciate, the clock signal CLK may include multiple synchronized clock signals at varying rates for the various operations of the multi-function handheld device.

Handheld device 40 functions in a similar manner to handheld device 10 of FIG. 1 with regard to exchanging data with the host device (i.e., when the handheld device is in the first operational mode). In addition, while exchanging data with the host, the handheld device 40 may store digital information received via one of the multimedia input devices 44, 46, and 54. For example, a voice recording received via the microphone 46 may be provided as multimedia input data 58, digitized via the multimedia module 24 and digitally stored in memory 16. Similarly, video recordings may be captured via the video capture device 44 (e.g., a digital camera, a camcorder, VCR output, DVD output, etc.) and processed by the multimedia module 24 for storage as digital video data in memory 16. Further, the key pad 54 (which may be a keyboard, touch screen interface, or other mechanism for inputting text information) provides text data to the multimedia module 24 for storage as digital text data in memory 16. In this extension of the first operational mode, the processing module 20 arbitrates write access to the memory 16 among the various input sources (e.g., the host and the multimedia module).

When the handheld device 40 is in the second operational mode (i.e., not connected to the host), the handheld device records and/or playbacks multimedia data that is stored in the memory 16. Note that the data provided by the host when the handheld device 40 was in the first operational mode includes the multimedia data. The playback of the multimedia data is similar to the playback described with reference to the handheld device 10 of FIG. 1. In this embodiment, depending on the type of multimedia data 34, the rendered output data 36 may be provided to one or more of the multimedia output devices via one of the plurality of programmable drivers 70. For example, rendered audio data may be provided to the headphone jack 52 an/or to the speaker 50, while rendered video and/or text data may be provided to the display 48.

The handheld device 40 may also record multimedia data 34 while in the second operational mode. For example, the handheld device 40 may store digital information received via one of the multimedia input devices 44, 46, and 54.

FIG. 3 is a schematic block diagram of an embodiment of a programmable driver 70 that includes a first driver 74, a second driver 76, and a controller 72. The inputs of each of the drivers 74 and 76 are coupled to receive a signal 75, which may be an analog or digital signal corresponding to rendered data from the multimedia module 24. The drivers 74 and 76 drive (i.e., increase the power level) the signal 75 on to a line coupled to an IC pin based on the state of an output enable signal 82 and the drive control signal 78. The line may be a headphone jack, speakers, video and/or text display, etc. As one of average skill in the art will appreciate, the programmable driver may be used to drive other types of transmission lines that have a varying load or, depending on a state of operation, have a different load. Such transmission lines may be coupled to memory devices, other integrated circuits, between printed circuit boards, etc.

The processing module 20, while performing an algorithm 30, determines whether the programmable driver 70 is to be activated or deactivated. If the programmable driver is to be deactivated, the processing module 20 sets the output enable 82 in a second state (e.g., a logic zero). If, however, the programmable driver 70 is to be activated, the processing module 20 sets the output enable 82 in a first state (e.g., a logic one state). With the output enable signal 82 in the first state, the first driver 74 is in an active mode such that it drives the signal 75 on to the line. With the output enable signal 82 in the first state, the controller 72, which may be a state machine, a processor, or within the processing module 20, determines whether the second driver 76 is to be activated based on the load requirements and/or signal strength settings 80. The load requirements and/or signal strength settings 80 may be programmed into a state machine, stored in memory and indexed based on the current operation being performed, or determined on an as need basis by the processing module 20.

For example, if the IC pin is coupled to a headphone jack that requires a maximum power level of 25 mW (milliwatts) and the first driver 74 is capable of outputting a drive signal of 50 mW, then the processing module 20 sets the load requirements and/or signal strength settings 80 to a first state. The controller 72 interprets the first state of the settings 80 to place the drive control signal 78 in a state that places the second driver 76 in a high impedance state such that it is deactive. If, however, the IC pin is coupled to speakers that require a maximum power level of 100 mW, then the processing module sets the load requirements and/or signal strength settings 80 to a second state. The controller 72 interprets the second state of the settings 80 to place the driver control signal 78 in a state that activates the second driver 76. If the second driver 76 is capable of outputting a driver of 50 mW, then, in parallel with the first driver 74, the resulting output drive signal has a power level of up to 100 mW.

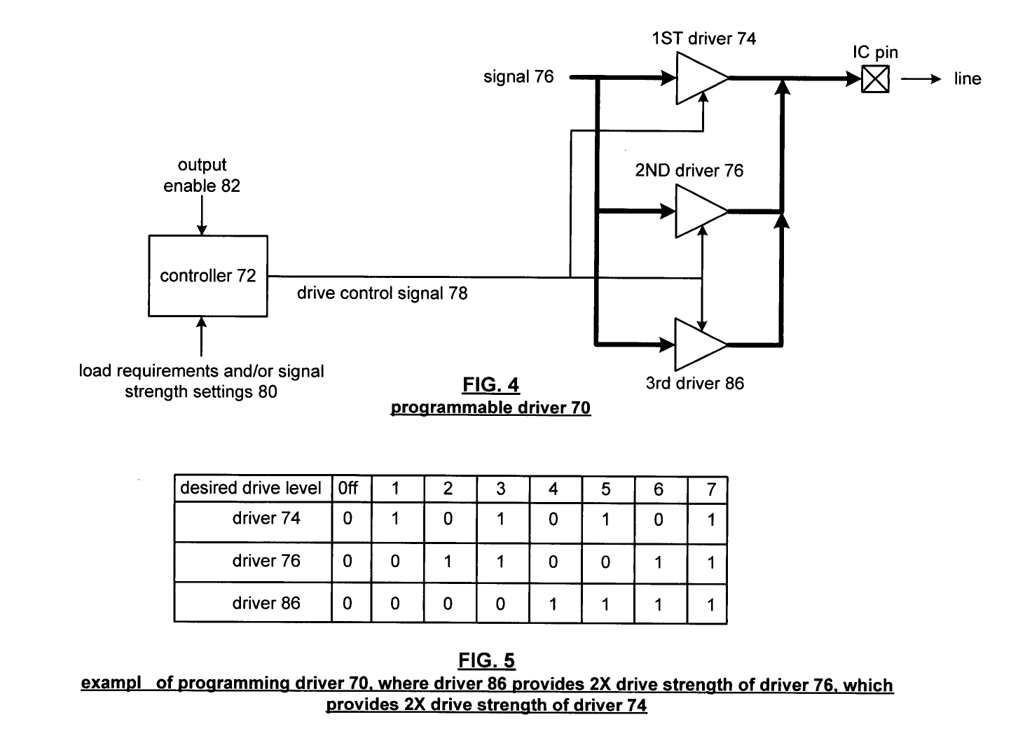

FIG. 4 is a schematic block diagram of another embodiment of a programmable driver 70. In this embodiment, the programmable driver 70 includes a plurality of drivers 74, 76, and 86, and the controller 72 to provide multiple different levels of output drive strength. For example and with reference to both FIGS. 4 and 5, assume that driver 86 provides twice the drive strength as driver 76, which, in turn, provides twice the drive strength as driver 74. As such, eight different drive strengths may be obtained. When the output enable 82 is in the second state, which indicates that the programmable driver 70 is to be deactivated, the controller 72 generates the drive control signal 78 such that the drivers 74, 76, and 86 are in a high impedance state (i.e., deactivated). This corresponds to the “off” desired power level.

With the output enable 82 in the first state to indicate that the programmable driver 70 is to be active, the controller 72 interprets the load requirements and/or signal strength settings 80 to generate one of seven different states for the drive control signal 78. Each state of the drive control signal 78 corresponds to a different desired drive level. Assume that the first desired drive level is the lowest active drive level and the seventh desired drive level is the highest active drive level. In this instance, when the settings 80 indicate the first desired drive level is needed, the controller 72 generates the drive control signal 78 to enable driver 74 and to disable drivers 76 and 86. When the settings 80 indicate a second desired drive level is needed, the controller 72 generates the drive control signal 78 to enable driver 76 and to disable drivers 74 and 86. When the settings 80 indicate a third desired drive level is needed, the controller 72 generates the drive control signal 78 to enable drivers 74 and 76 and to disable driver 86. The remaining power levels are produced as shown in FIG. 5.

As one of average skill in the art will appreciate, the programmable driver 70 of FIG. 4 may include more or less than three drivers. As one of average skill in the art will further appreciate, the drive levels of the drivers of the programmable driver 70 may have different drive levels or similar drive levels, which may range from a few mW to hundreds of mW.

As one of average skill in the art will appreciate, the term “substantially” or “approximately”, as may be used herein, provides an industry-accepted tolerance to its corresponding term. Such an industry-accepted tolerance ranges from less than one percent to twenty percent and corresponds to, but is not limited to, component values, integrated circuit process variations, temperature variations, rise and fall times, and/or thermal noise. As one of average skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of average skill in the art will also appreciate, inferred coupling (i.e., where one element is coupled to another element by inference) includes direct and indirect coupling between two elements in the same manner as “operably coupled”. As one of average skill in the art will further appreciate, the term “compares favorably”, as may be used herein, indicates that a comparison between two or more elements, items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

The preceding discussion has presented a programmable driver that may be used in integrated circuits of a handheld multiple function devices to improve battery life. As one of average skill in the art will appreciate, other embodiments may be derived from the teachings of the invention contained herein without deviating from the scope of the claims.

What is claimed is:

1. A programmable driver comprises:
a first driver;
a second driver operably coupled in parallel with the first driver to drive a signal on to a line at a first drive level when a drive control signal is in a first state and wherein, when the drive control signal is in a second state, the second driver is in a high-impedance state such that the first driver drives the signal on to the line at a second drive level, wherein the first drive level is greater than the second drive level; and
controller operably coupled to generate the drive control signal based on load requirements of the line.

2. The programmable driver of claim 1, wherein the first driver further comprises a tri-state driver that is placed in a high impedance state when an output enable signal is in a first state and is placed in an active state when the output enable signal is in a second state.

3. The programmable driver of claim 2, wherein the controller further functions to generate the drive control signal in the second state when the output enable signal is in the first state.

4. The programmable driver of claim 1 further comprises:
a third driver operably coupled in parallel with the first driver to drive the signal on to the line at a third drive level when the drive control signal is in a third state and wherein, when the drive control signal is in the second state, the third driver is in the high-impedance state, wherein the third drive level is greater than the second drive level.

5. The programmable driver of claim 4, wherein the controller further functions to:
generate the drive control signal in a fourth state, wherein, with the drive control signal in the fourth state, the first, second, and third drivers are coupled on parallel to drive the signal on to the line at a fourth drive level, wherein the fourth drive level is greater than the third.

6. The programmable driver of claim 1, wherein the controller further functions to determine the load requirement based on a load impedance on the line or an output signal strength setting.

7. A programmable driver comprises:
a plurality of tri-state drivers; and
controller operably coupled to the plurality of tri-state drivers, wherein, based on a line drive requirement, the controller generates a drive control signal that activates at least one of the plurality of tri-state drivers to drive a signal on to a line at a drive level corresponding to the line drive requirement.

8. The programmable driver of claim 7, wherein each of the plurality of tri-state drivers, when in an active mode, provides an individual drive level.

9. The programmable driver of claim 8, wherein the controller further functions to generate the drive control signal by:
determining a desired drive level based on the line drive requirement;
identifying the at least one of the plurality of tri-state drivers based on the desired drive level and the individual drive levels of each of the plurality of tri-state drivers; and
generating the drive control signal to active the at least one of the plurality of tri-state drivers.

10. The programmable driver of claim 7, wherein the controller comprises a state machine to generate the drive control signal based on the line drive requirement.

11. The programmable driver of claim 7, wherein the controller further functions to generate the drive control signal to place the plurality of tri-state drivers in a high impedance state when an output enable signal is in a first state.

12. The programmable driver of claim 7, wherein the controller further functions to determine the line drive requirement based on a load impedance on the line or an output signal strength setting.

13. A multiple function system on a chip integrated circuit comprises:
a plurality of interface modules operably coupled to receive digital data from a corresponding plurality of external sources;
a digital to analog converter operably coupled to convert digital signals into analog signals;
a processing module;
on-chip memory operably coupled to the processing module, wherein the on-chip memory at least temporarily stores operational instructions that cause the processing module to produce the digital signals from the digital data; and
programmable driver that includes:
a first driver;
a second driver operably coupled in parallel with the first driver to drive the analog signals on to a line at a first drive level when a drive control signal is in a first state and wherein, when the drive control signal is in a second state, the second driver is in a high-impedance state such that the first driver drives the analog signals on to the line at a second drive level, wherein the first drive level is greater than the second drive level; and
controller operably coupled to generate the drive control signal based on load requirements of the line.

14. The multiple function system on a chip integrated circuit of claim 13, wherein the first driver further comprises a tri-state driver that is placed in a high impedance state when an output enable signal is in a first state and is placed in an active state when the output enable signal is in a second state.

15. The multiple function system on a chip integrated circuit of claim 14, wherein the controller further functions to generate the drive control signal in the second state when the output enable signal is in the first state.

16. The multiple function system on a chip integrated circuit of claim 13, wherein the programmable driver further comprises:
a third driver operably coupled in parallel with the first driver to drive the analog signals on to the line at a third drive level when the drive control signal is in a third state and wherein, when the drive control signal is in the second state, the third driver is in the high-impedance state, wherein the third drive level is greater than the second drive level.

17. The multiple function system on a chip integrated circuit of claim 16, wherein the controller further functions to:
generate the drive control signal in a fourth state, wherein, with the drive control signal in the fourth state, the first, second, and third drivers are coupled on parallel to drive the analog signals on to the line at a fourth drive level, wherein the fourth drive level is greater than the third.

18. The multiple function system on a chip integrated circuit of claim 13, wherein the controller further functions to determine the load requirement based on a load impedance on the line or an output signal strength setting.

19. A multiple function system on a chip integrated circuit comprises:
a plurality of interface modules operably coupled to receive digital data from a corresponding plurality of external sources;
a digital to analog converter operably coupled to convert digital signals into analog signals;
a processing module;
on-chip memory operably coupled to the processing module, wherein the on-chip memory at least temporarily stores operational instructions that cause the processing module to produce the digital signals from the digital data; and
programmable driver that includes:
a plurality of tri-state drivers; and
controller operably coupled to the plurality of tri-state drivers, wherein, based on a line drive requirement, the controller generates a drive control signal that activates at least one of the plurality of tri-state drivers to drive a signal on to a line at a drive level corresponding to the line drive requirement.

20. The multiple function system on a chip integrated circuit of claim 19, wherein each of the plurality of tri-state drivers, when in an active mode, provides an individual drive level.

21. The multiple function system on a chip integrated circuit of claim 20, wherein the controller further functions to generate the drive control signal by:
determining a desired drive level based on the line drive requirement;
identifying the at least one of the plurality of tri-state drivers based on the desired drive level and the individual drive levels of each of the plurality of tri-state drivers; and
generating the drive control signal to active the at least one of the plurality of tri-state drivers.

22. The multiple function system on a chip integrated circuit of claim 19, wherein the controller comprises a state machine to generate the drive control signal based on the line drive requirement.

23. The multiple function system on a chip integrated circuit of claim 19, wherein the controller further functions to generate the drive control signal to place the plurality of tri-state drivers in a high impedance state when an output enable signal is in a first state.

24. The multiple function system on a chip integrated circuit of claim 19, wherein the controller further functions to determine the line drive requirement based on a load impedance on the line or an output signal strength setting.
